(19) United States
(12) Patent Application Publication
(10) Pub. No.: US 2013/0307599 A1
(43) Pub. Date: Nov. 21, 2013

(54) INPUT BUFFER

(71) Applicant: Haeng Seon CHAE, Seoul (KR)

(72) Inventor: Haeng Seon CHAE, Seoul (KR)

(73) Assignee: SK HYNIX INC., Icheon-si (KR)

(21) Appl. No.: 13/615,268

(22) Filed: Sep. 13, 2012

(30) Foreign Application Priority Data
May 21, 2012 (KR) 10-2012-0053903

(51) Int. Cl. H03L 7/00

(52) U.S. Cl. 327/161

(57) ABSTRACT

An input buffer includes a select signal generation unit configured to detect a phase of a clock at generation times of first and second delayed signals according to a test signal, and generate first and second select signals according to a phase combination of the detected phase of the clock; and a delay output unit configured to output any one of the first and second delayed signals as a delayed command address in response to the first and second select signals and the test signal.

### CROSS-REFERENCE TO RELATED APPLICATION

The present application claims priority under 35 U.S.C 119(a) to Korean Patent Application No. 10-2012-0053903 filed on May 21, 2012 in the Korean Intellectual Property Office, which is incorporated herein by reference in its entirety as set forth in full.

### BACKGROUND

A semiconductor memory device has continuously been developed to elevate the degree of integration and increase operation speeds. In order to increase operation speeds, a so-called synchronous type semiconductor memory device which operates in synchronization with a clock provided from an outside source has been disclosed. The input buffer of such a synchronous type semiconductor memory device receives a command address in synchronization with the edge of the clock and generates an internal command address.

FIG. 1 is a block diagram showing a conventional input buffer.

The conventional input buffer includes a delay unit 11 and a buffer unit 12. The delay unit 11 delays a command address CA by a predetermined amount of time and generates a delayed command address CAd. The buffer unit 12 receives the delayed command address CAd in synchronization with a clock CLK and generates an internal command address ICA.

The delay unit 11 is constituted by a plurality of inverters (not shown), and the operation characteristics of the inverters may change according to a variation in PVT (process, voltage and temperature). If the operation characteristics of the inverters change, the delay unit 11 cannot uniformly delay the command address CA, and thus, the generation time of the delayed command address CAd changes. If the generation time of the delayed command address CAd changes, timings of the clock CLK and the delayed command address CAd do not match each other. Consequently, as the buffer unit 12 cannot receive the delayed command address CAd in synchronization with the clock CLK, it cannot generate the internal command address ICA.

### SUMMARY

An embodiment of the present invention relates to an input buffer which can receive a command address in synchronization with a clock and generate an internal command address even when a variation occurs in PVT (process, voltage and temperature).

In one embodiment, an input buffer includes: a select signal generation unit configured to detect a phase of a clock at generation times of first and second delayed signals according to a test signal, and generate first and second select signals according to a phase combination of the detected phase of the clock; and a delay output unit configured to output any one of the first and second delayed signals as a delayed command address in response to the first and second select signals and the test signal.

In another embodiment, an input buffer includes: a delay output unit configured to output any one of first and second delayed signals as a delayed command address in response to first and second select signals which are generated according to a phase combination of a detected phase of a clock and a test signal; and a buffer unit configured to receive the delayed command address in synchronization with the clock and generate an internal command address.

### BRIEF DESCRIPTION OF THE DRAWINGS

The above and other aspects, features and other advantages will be more clearly understood from the following detailed description taken in conjunction with the accompanying drawings, in which:

FIG. 1 is a block diagram showing a conventional input buffer;

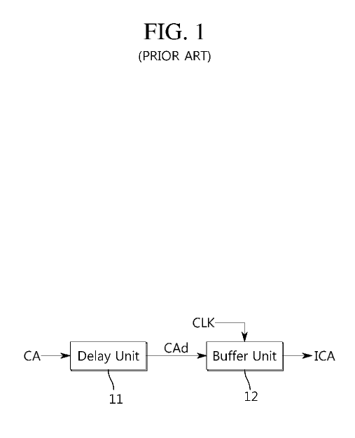

FIG. 2 is a block diagram showing an input buffer in accordance with an embodiment of the present invention;

FIG. 3 is a block diagram showing a select signal generation unit included in the input buffer shown in FIG. 2;

FIG. 4 is a table showing relationships among a test signal, code signals and select signals in the case where the input buffer is inputted with a command address in synchronization with a rising edge of a clock;

FIG. 5 is a table showing relationships among the test signal, the code signals and the select signals in the case where the input buffer is inputted with the command address in synchronization with a falling edge of the clock;

FIG. 6 is a circuit diagram of the delay output unit included in the input buffer shown in FIG. 2;

FIG. 7 is a timing diagram explaining an operation of the delay output unit shown in FIG. 2 outputting a first delayed signal as a delayed command address; and

FIG. 8 is a timing diagram explaining an operation for the delay output unit shown in FIG. 2 to output a second delayed signal as a delayed command address.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

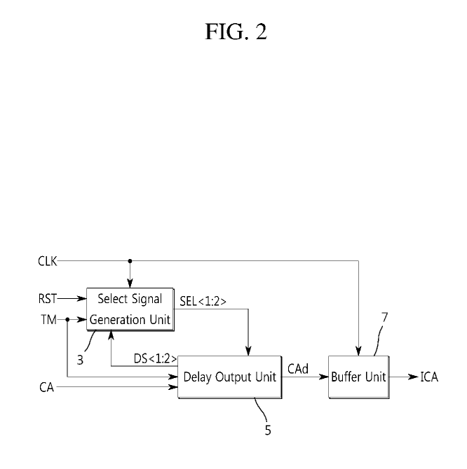

FIG. 2 is a block diagram showing an input buffer in accordance with an embodiment of the present invention.

Referring to FIG. 2, an input buffer in accordance with an embodiment of the present invention includes a select signal generation unit 3, a delay output unit 5, and a buffer unit 7. The select signal generation unit 3 is configured to receive a reset signal RST and generate first and second select signals SEL<1:2> of logic low levels in a test mode. Also, the select signal generation unit 3 is configured to detect the phase of a clock CLK when first and second delayed signals DS<1:2> are generated. Further, the select signal generation unit 3 is configured to generate the first and second select signals SEL<1:2> when the test mode has completed according to a phase combination of the clock CLK. The delay output unit 5 is configured to delay a command address CA for first and second time periods in the test mode, where a time period may be an interval of time. The delay output unit 5 may also generate the first and second delayed signals DS<1:2>. Also, the delay output unit 5 is configured to output any one of the first and second delayed signals DS<1:2> as a delayed command address CAd when the test mode has completed in response to the first and second select signals SEL<1:2>. The buffer unit 7 is configured to receive the delayed command address CAd in synchronization with the clock CLK and generate an internal command address ICA.

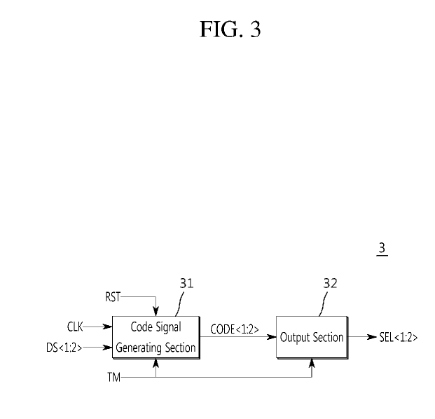

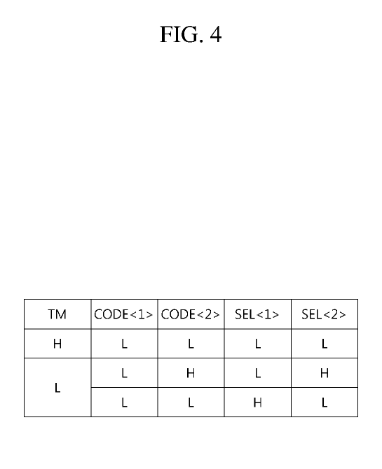

Referring to FIG. 3, the select signal generation unit 3 includes a code signal generating section 31 and an output section 32. Hereinbelow, a case in which the input buffer receives the command address CA in synchronization with the rising edge of the clock CLK will be described with reference to FIG. 4.

The code signal generating section 31 may be substantially similar to a phase detection circuit which is generally known in the art. The code signal generating section 31 realized in this way is configured to receive the reset signal RST and a test signal TM and generate first and second code signals CODE<1:2> of logic low levels. The reset signal RST includes a pulse which is generated when the test mode starts, that is, a time when the test signal TM is enabled to a logic high level. The code signal generating section 31 generates the first and second code signals CODE<1:2> of the logic low levels when the reset signal RST is generated. The test signal TM is enabled to the logic high level in the test mode. The code signal generating section 31 detects the phase of the clock CLK at generation times of the first and second delayed signals DS<1:2>, when the test signal TM is enabled to the logic high level, and the code signal generating section 31 generates the first and second code signals CODE<1:2> when the test signal TM is disabled to a logic low level. The first and second delayed signals DS<1:2> are generated by delaying the command address CA for the first and second time periods, respectively. The command address CA may be generated to a logic high level or a logic low level. Also, the first time period may be shorter than the second time period.

Describing in detail the case in which the test signal TM is disabled to the logic low level, with reference to FIG. 4, if the phase of the clock CLK has a logic low level and a logic high level at the times when the first and second delayed signals DS<1:2> are respectively generated, the code signal generating section 31 generates the first and second code signals CODE<1:2> of a <L, H> combination. Also, if the phase of the clock CLK has the logic low level at both times when the first and second delayed signals DS<1:2> are respectively generated, the code signal generating section 31 generates the first and second code signals CODE<1:2> of a <L, L> combination.

The output section 32 generates the first and second select signals SEL<1:2> of logic low levels when the test signal TM is enabled to the logic high level. Also, the output section 32 generates the first and second select signals SEL<1:2> according to the combination of the first and second code signals CODE<1:2> when the test signal TM is disabled to the logic low level. Thus, the output section may be configured to generate the first and second select signals SEL<1:2> according to the combination of the first and second code signals CODE<1:2> and according to the test signal TM. Describing this in detail with reference to FIG. 4, the first select signal SEL<1> and the second select signal SEL<2> of the logic low levels are generated when the test signal TM has the logic high level. When the test signal TM has the logic low level and the first and second code signals CODE<1:2> have the <L, H> combination, the output section 32 generates the first select signal SEL<1> of the logic low level and the second select signal SEL<2> of a logic high level. Further, when the test signal TM has the logic low level and the first and second code signals CODE<1:2> have the <L, L> combination, the output section 32 generates the first select signal SEL<1> of a logic high level and the second select signal SEL<2> of the logic low level.

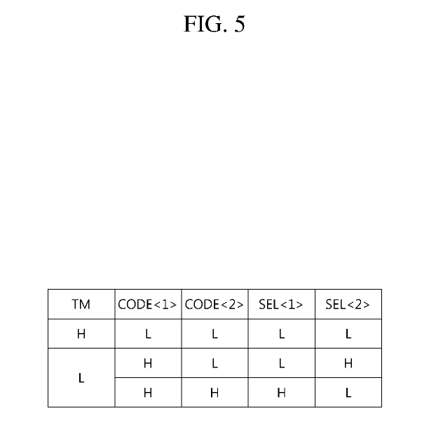

Hereinbelow, a case in which the input buffer receives the command address CA in synchronization with the falling edge of the clock CLK will be described with reference to FIG. 5.

The code signal generating section 31 may be substantially similar to a phase detection circuit which is generally known in the art. The code signal generating section 31 realized in this way is configured to receive the reset signal RST and the test signal TM and generate the first and second code signals CODE<1:2> of the logic low levels when the reset signal RST is generated. The reset signal RST includes the pulse which is generated at the time when the test mode starts, that is, the time when the test signal TM is enabled to the logic high level. The code signal generating section 31 generates the first and second code signals CODE<1:2> of the logic low levels when the reset signal RST is generated. The test signal TM is enabled to the logic high level in the test mode. The code signal generating section 31 detects the phase of the clock CLK at the generation times of the first and second delayed signals DS<1:2>, when the test signal TM is enabled to the logic high level, and generates the first and second code signals CODE<1:2> when the test signal TM is disabled to the logic low level. The first and second delayed signals DS<1:2> are generated by delaying the command address CA for the first and second time periods, respectively. The command address CA may be generated to the logic high level or the logic low level. Also, the first period may be shorter than the second period.

Describing in detail the case in which the test signal TM is disabled to the logic low level, with reference to FIG. 5, if the phase of the clock CLK has the logic high level and the logic low level at the times when the first and second delayed signals DS<1:2> are respectively generated, the code signal generating section 31 generates the first and second code signals CODE<1:2> of a <H, L> combination. Also, if the phase of the clock CLK has the logic low level at both times when the first and second delayed signals DS<1:2> are generated, the code signal generating section 31 generates the first and second code signals CODE<1:2> of a <H, H> combination.

The output section 32 generates the first and second select signals SEL<1:2> of the logic low levels when the test signal TM is enabled to the logic high level. Also, the output section 32 generates the first and second select signals SEL<1:2> according to the combination of the first and second code signals CODE<1:2> when the test signal TM is disabled to the logic low level. Describing this in detail with reference to FIG. 5, the first select signal SEL<1> and the second select signal SEL<2> of the logic low levels are generated when the test signal TM has the logic high level. When the test signal TM has the logic low level and the first and second code signals CODE<1:2> have the <H, L> combination, the output section 32 generates the first select signal SEL<1> of the logic low level and the second select signal SEL<2> of the logic high level. Further, when the test signal TM has the logic low level and the first and second code signals CODE<1:2> have the <H, H> combination, the output section 32 generates the first select signal SEL<1> of the logic high level and the second select signal SEL<2> of the logic low level.

The select signal generation unit 3 configured as described above generates the first and second select signals SEL<1:2> of the logic low levels in the test mode. Also, the select signal generation unit 3 detects the phase of the clock CLK at the generation times of the first and second delayed signals DS<1:2>. Moreover, the select signal generation unit 3 generates the first and second select signals SEL<1:2> according to the combination of the first and second code signals CODE<1:2> when the test mode has completed.

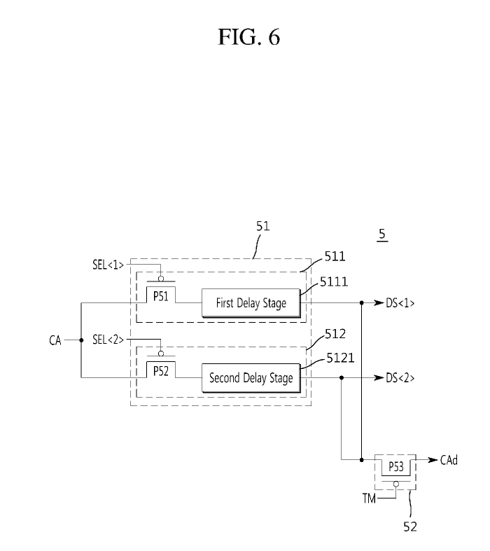

Referring to FIG. 6, the delay output unit 5 includes a signal generating section 51 and a signal transfer section 52. The signal generating section 51 includes a first signal generation part 511 and a second signal generation part 512. The first signal generation part 511 includes one PMOS transistor P51 and a first delay stage 5111. The first signal generation part 511 configured in this way delays the command address CA for the first period by the first delay stage 5111 in response to the first select signal SEL<1>, such that when the first select signal SEL<1> has the logic low level and generates the first delayed signal DS<1>.

The second signal generation part 512 includes one PMOS transistor P52 and a second delay stage 5121. The second signal generation part 512 configured in this way delays the command address CA for the second period by the second delay stage 5121 in response to the second select signal SEL<2>, such that when the second select signal SEL<2> has the logic low level and generates the second delayed signal DS<2>.

The signal transfer section 52 is includes a PMOS transistor P53. The signal transfer section 52 configured in this way may transfer any one of the first and second delayed signals DS<1:2> as the delayed command address CAd by outputting any one of the first and second delayed signals DS<1:2> as the delayed command address CAd when the test signal TM is disabled to the logic low level. The test signal TM is enabled to the logic high level in the test mode.

The delay output unit 5 configured in this way delays the command address CA for the first and second time periods during the test mode and generates the first and second delayed signals DS<1:2>. Further, the delay output unit 5 outputs any one of the first and second delayed signals DS<1:2> as the delayed command address CAd in response to the first and second select signals SEL<1:2> when the test mode has completed.

The buffer unit 7 receives the delayed command address CAd in synchronization with the clock CLK and generates the internal command address ICA.

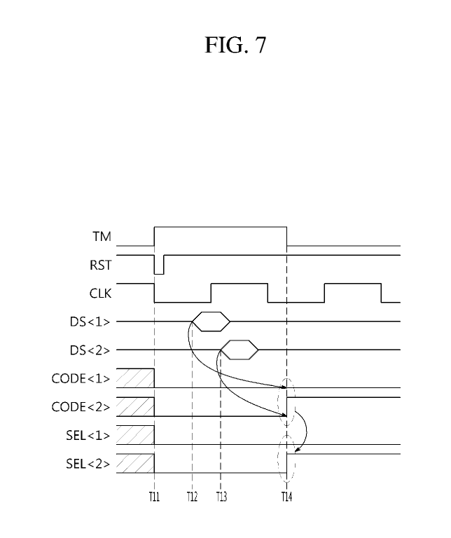

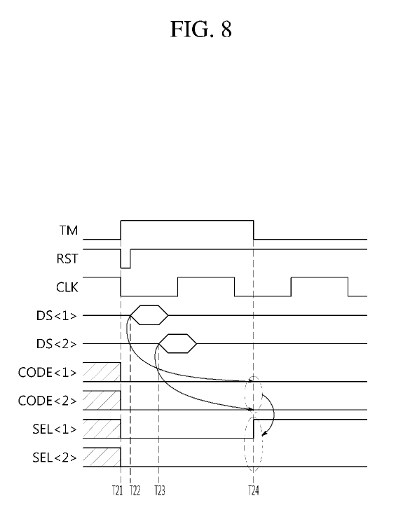

Operations of the input buffer configured as mentioned above will be described with reference to FIGS. 7 and 8 by exemplifying when the input buffer receives the command address CA in synchronization with the rising edge of the clock CLK.

FIG. 7 is a timing diagram explaining an operation for the delay output unit 5 shown in FIG. 2 to output the first delayed signal as the delayed command address.

First, as the test signal TM is enabled to the logic high level at T11, the test mode is started. The code signal generating section 31 of the select signal generation unit 3 generates the first and second code signals CODE<1:2> of the logic low levels when the reset signal RST is generated. The output section 32 of the select signal generation unit 3 generates the first and second select signals SEL<1:2> of the logic low levels. The delay output unit 5 delays the command address CA for the first and second time periods and generates the first and second delayed signals DS<1:2>.

The code signal generating section 31 of the select signal generation unit 3 receives the first and second delayed signals DS<1:2>, detects the phase of the clock CLK at T12 as a time when the first delayed signal DS<1> is generated, and detects the phase of the clock CLK at T13 as a time when the second delayed signal DS<2> is generated. The phase of the clock CLK at T12 has the logic low level, and the phase of the clock CLK at T13 has the logic high level.

Next, since the test signal TM is disabled to the logic low level at T14, the test mode is ended. The code signal generating section 31 generates the first and second code signals CODE<1:2> of the <L, H> combination. Since the first and second code signals CODE<1:2> have the <L, H> combination, the output section 32 of the select signal generation unit 3 generates the first select signal SEL<1> of the logic low level and the second select signal SEL<2> of the logic high level. Since the first select signal SEL<1> has the logic low level and the second select signal SEL<2> has the logic high level, the delay output unit 5 outputs the first delayed signal DS<1> as the delayed command address CAd.

The buffer unit 7 receives the delayed command address CAd in synchronization with the clock CLK and generates the internal command address ICA.

FIG. 8 is a timing diagram explaining an operation for the delay output unit 5 shown in FIG. 2 to output the second delayed signal as the delayed command address.

First, as the test signal TM is enabled to the logic high level at T21, the test mode is started. The code signal generating section 31 of the select signal generation unit 3 generates the first and second code signals CODE<1:2> of the logic low levels when the reset signal RST is generated. The output section 32 of the select signal generation unit 3 generates the first and second select signals SEL<1:2> of the logic low levels. The delay output unit 5 delays the command address CA by the first and second periods and generates the first and second delayed signals DS<1:2>.

The code signal generating section 31 of the select signal generation unit 3 receives the first and second delayed signals DS<1:2>, detects the phase of the clock CLK at T22 as a time when the first delayed signal DS<1> is generated, and detects the phase of the clock CLK at T23 as a time when the second delayed signal DS<2> is generated. The phase of the clock CLK at T22 has the logic low level, and the phase of the clock CLK at T23 has the logic low level.

Next, as the test signal TM is disabled to the logic low level at T24, the test mode is ended. The code signal generating section 31 generates the first and second code signals CODE<1:2> of the <L, L> combination. Since the first and second code signals CODE<1:2> have the <L, L> combination, the output section 32 of the select signal generation unit 3 generates the first select signal SEL<1> of the logic high level and the second select signal SEL<2> of the logic low level. Since the first select signal SEL<1> has the logic high level and the second select signal SEL<2> has the logic low level, the delay output unit 5 outputs the second delayed signal DS<2> as the delayed command address CAd.

The buffer unit 7 receives the delayed command address CAd in synchronization with the clock CLK and generates the internal command address ICA.

As is apparent from the above descriptions, in the input buffer according to the embodiment of the present invention, the delay period of a command address is determined on the basis of a clock in a test mode. As a consequence, it is possible to receive the command address in synchronization with the clock and generate an internal command address even when a variation occurs in PVT (process, voltage and temperature).

As is apparent from the above descriptions, according to the embodiment of the present invention, an input buffer can receive a command address in synchronization with a clock and generate an internal command address even when a variation occurs in PVT (process, voltage and temperature).

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. An input buffer comprising:
a select signal generation unit configured to detect a phase of a clock at generation times of first and second delayed signals according to a test signal, and generate first and second select signals according to a phase combination of the detected phase of the clock; and
a delay output unit configured to output any one of the first and second delayed signals as a delayed command address in response to the first and second select signals and the test signal.

2. The input buffer according to claim 1, wherein the first and second delayed signals are generated by delaying a command address by first and second periods, respectively.

3. The input buffer according to claim 2, wherein the first period is shorter than the second period.

4. The input buffer according to claim 1, wherein the select signal generation unit generates code signals by detecting the phase of the clock at the generation times of the first and second delayed signals, and generates the first and second select signals according to a combination of the code signals.

5. The input buffer according to claim 1, wherein the select signal generation unit comprises:
a code signal generating section configured to detect the phase of the clock at the generation times of the first and second delayed signals according to the test signal and generate the code signals; and
an output section configured to generate the first and second select signals according to the combination of the code signals according to the test signal.

6. The input buffer according to claim 2, wherein the delay output unit comprises:
a signal generating section configured to delay the command address for the first and second time periods in response to the first and second select signals and generate the first and second delayed signals.

7. The input buffer according to claim 6, wherein the signal generating section comprises:
a first signal generation part configured to delay the command address for the first period in response to the first select signal and generate the first delayed signal; and
a second signal generation part configured to delay the command address for the second period in response to the second select signal and generate the second delayed signal.

8. The input buffer according to claim 7, wherein the delay output unit further comprises:
a signal transfer section configured to transfer any one of the first and second delayed signals as the delayed command address according to the test signal.

9. The input buffer according to claim 1, further comprising:
a buffer unit configured to receive the delayed command address in synchronization with the clock and generate an internal command address.

10. An input buffer comprising:
a delay output unit configured to detect a phase of a clock at generation times of first and second delayed signals, and output any one of the first and second delayed signals as a delayed command address in response to first and second select signals which are generated according to a phase combination of the detected phase of a clock and a test signal; and
a buffer unit configured to receive the delayed command address in synchronization with the clock and generate an internal command address.

11. The input buffer according to claim 10, further comprising:
a select signal generation unit configured to generate the first and second select signals according to the test signal.

12. The input buffer according to claim 11, wherein the first and second delayed signals are generated by delaying a command address by first and second periods, respectively.

13. The input buffer according to claim 12, wherein the first period is shorter than the second period.

14. The input buffer according to claim 11, wherein the select signal generation unit comprises:
a code signal generating section configured to detect the phase of the clock at the generation times of the first and second delayed signals according to the test signal and generate code signals; and
an output section configured to generate the first and second select signals according to the combination of the code signals according to the test signal.

15. The input buffer according to claim 11, wherein the delay output unit comprises:
a signal generating section configured to delay the command address for the first and second periods in response to the first and second select signals and generate the first and second delayed signals.

16. The input buffer according to claim 15, wherein the signal generating section comprises:
a first signal generation part configured to delay the command address for the first period in response to the first select signal and generate the first delayed signal; and
a second signal generation part configured to delay the command address by the second period in response to the second select signal and generate the second delayed signal.

17. The input buffer according to claim 16, wherein the delay output unit further comprises:
a signal transfer section configured to transfer any one of the first and second delayed signals as the delayed command address according to the test signal.
